(19) United States
(12) Patent Application Publication
(10) Pub. No.: US 2007/0125525 A1
(43) Pub. Date: Jun. 7, 2007

(54) Arrangement used to secure a fan frame

(75) Inventor: Reinhard Heine, Remseck (DE)

Correspondence Address: FOLEY AND LARDNER LLP;SUITE 500, 3000 K STREET NW, WASHINGTON, DC, 20007, US

(73) Assignee: BEHR GmbH & CO. KG

(21) Appl. No.: 10/575,887

(22) PCT Filed: Sep. 13, 2004
(86) PCT No.: PCT/EP04/10187

§ 371 Date: Aug. 15, 2006

(30) Foreign Application Priority Data
Oct. 17, 2003 (DE) 103 49 139.2

(51) Int. Cl. H01L 23/467; F01P 1/00

(52) U.S. Cl. 165/121; 123/41.56

(57) ABSTRACT

The invention relates to an arrangement which is used to secure a fan frame (2) to a heat exchanger (3). Said heat exchanger (3) comprises a collecting tank provided with retaining means and the fan frame (2) comprises a frame provided with a support device and/or an additional rib and securing means which interact with the retaining means of the collecting tanks (8, 9).

The invention relates to an arrangement used to secure a fan frame and/or additional heat exchangers to a heat exchanger according to the preamble of patent claim 1 and according to the preamble of patent claim 2.

Fan frames, also called fan cowls, are accessories to a heat exchanger and are often secured directly to the heat exchanger. Fan frames have the task of collecting on the air outlet side the air flowing through the heat exchanger and of delivering this air to the frame aperture, in which a fan is arranged, as completely and as free of loss as possible. The fan frame must therefore bear as sealingly as possible against the heat exchanger so that no “infiltrated air” is sucked in by the fan. Particularly in the case of motor vehicles, that is to say coolants/air coolers, the fan cowl is to be secured as simply as possible, without additional aids and, furthermore, so as to be rattle-free. There is mostly little installation space available, particularly in the direction of travel of the motor vehicle, that is to say in the X-direction, for installing the fan cowl. Since, when the motor vehicle is in operation, the fan cowls, which carry not only the fan, but also the fan motor, are exposed to high vibrational stress and to acceleration and deceleration forces, known fan cowls are secured to the heat exchanger or coolant cooler on all four sides, that is to say all-round. In this case, on the one hand, the headers or coolant boxes or side parts of the heat exchanger serve as securing points on the heat exchanger.

The applicant's DE-A 35 36 457 disclosed, for what is known as a downdraft cooler with vertically running tubes and with an upper and a lower water box, an air cowl securing which is characterized by latch and snap connections, on the one hand, on the water boxes and, on the other hand, on the side parts of the cooler. The side parts form with the water boxes a stable framework, thus affording leaktight bearing contact and uniform securing over the circumference of the fan cowl. The fan cowl is secured and latched on the cooler without additional components, that is to say by injection-molded securing means.

The applicant's DE-A 195 26 286 disclosed a variable fan cowl securing (for variable cooler sizes), in which the fan cowl is secured, on the one hand, to a coolant box of a coolant cooler and, on the other hand, to the ribbed tube block. The direct securing of the fan frame to the ribbed block takes place by clamping strips which are pressed into the ribs of the ribbed block, preferably into a prefabricated groove, and are braced. This securing is relatively complicated, since it requires at least one additional part, the second clamping strip, and additional retaining means. Furthermore, this securing can be employed advantageously only in the case of mechanically assembled ribbed tube blocks.

DE-C 42 44 037, from which the invention proceeds, disclosed a fan cowl securing for a motor vehicle cross-flow cooler, in which the fan cowl is secured, on the one hand, to the lateral coolant boxes and, on the other hand, to the side parts of the cooler, that is to say on four sides. The cooler itself is supported in the vehicle via securing tenons which are injection-molded onto the underside of the coolant boxes. The side parts are connected to the tube bottoms of the coolant boxes and to the tube/rib block (by soldering) and thus afford a relatively rigid securing base for the fan cowl. The individual securing points are configured such that, with the cooler installed, the fan frame can be inserted in the vehicle from the top downward, mounted and secured. This type of construction has proved appropriate, but require stable side parts on the cooler.

The object of the present invention is to provide an arrangement used for securing a fan frame of the type initially mentioned, which makes it possible to dispense with compact side parts and nevertheless makes it possible sufficiently to secure and seal off the fan cowl with respect to the heat exchanger. The object of the invention is also to provide an arrangement used for securing a fan frame and/or additional heat exchangers to a coolant cooler in a motor vehicle, with the result that the coolant boxes and the cooler block are relieved of load.

One object is achieved by means of the features of patent claim 1. According to the invention, on the framework of the fan frame, in particular between headers, one or more additional ribs are arranged, which cause a stiffening of the framework or of the fan frame, specifically in a direction which runs perpendicularly with respect to the end face, that is to say to the air inlet and outlet face, that is to say the air flow direction. This direction is designated as the X-direction. The additional ribs bring about an increase in the bending resistance of the framework in the X-direction. This ensures that the framework bears, free of distortion and of gaps, against the heat exchanger. The stiffening rib according to the invention affords the advantage that side parts on the heat exchanger can be dispensed with. The lack of securing of the fan frame to a side part is compensated by the additional rib which makes it possible for the fan frame to be secured only to the headers. This also affords a considerable simplification, on the one hand, for the heat exchanger and, on the other hand, for the securing between heat exchanger and fan frame which, according to the invention, has few securing points.

In advantageous refinements of the invention, the additional ribs may be optimized in terms of their bending resistance in the X-direction, that is to say they extend mainly in the X-direction or depth direction. In this case, the additional ribs advantageously cover the tube/rib block of the heat exchanger, thus affording the advantage that there is no need for additional construction space for the additional rib. The depth of the rib in the X-direction may advantageously be configured such that the maximum depth is reached at mid-length between the headers, that is to say the rib has the form of an isosceles triangle in a top view (in the Z-direction). This achieves the advantage that the highest bending resistance is obtained in the middle, this being appropriate for the stresses which occur. It is also advantageous if the fan frame is produced from plastic and the additional ribs are injection-molded on. This requires merely a once-only change in the plastic injection-molding die, and further costs are not incurred. For injection-molding reasons, it is advantageous, furthermore, that the wall thickness of the additional rib does not have to be increased, as compared with the remaining wall thickness of the fan frame, but remains approximately the same.

In a further advantageous refinement of the invention, the heat exchanger is designed as a coolant/air cooler of a motor vehicle, either as a downdraft cooler or preferably as a cross-flow cooler. It is precisely in motor vehicles where the constraints as regards the saving of weight and of construction space are especially severe, which is why the abovementioned advantages are particularly crucial here. Dispensing with two side parts saves costs for the cooler. The fan cowl can have a relatively short build in the X-direction on account of the stiffening ribs according to the invention, thus saving construction space in the engine space of the motor vehicle in the X-direction, without the framework of the fan frame becoming soft or unstable in the X-direction. In particular, acceleration and deceleration forces arise in the motor vehicle in this direction. Finally, the fan frame according to the invention also proves advantageous in the case of a cooling module, since the costs of the cooling module and its installation depth in the X-direction can consequently be reduced. The fan cowl is thus secured only on two sides, that is to say the coolant boxes, and, because of its bending resistance, bears with the other two sides sealingly against the heat exchanger. There is therefore no need for any further securing of the sides of the additional rib. Acceleration or deceleration forces which act on the framework are absorbed by the additional ribs and are introduced into the coolant boxes.

One object is also achieved by means of the features of patent claim 2. According to the invention, the fan frame or the heat exchanger or heat exchangers have supporting means for support on an abutment, for example part of a motor vehicle framework which also serves for supporting the heat exchanger by the supporting means of the latter.

In one preferred embodiment, the (lower and/or upper) securing points of the fan frame are combined, that is to say integrated, with the securing points of the coolant cooler in the motor vehicle to form common securing points. This integration affords the advantage that the forces resulting from the fan frame are introduced directly into the cooler support, that is to say into the associated supporting bearings in the motor vehicle. Consequently, on the one hand, the coolant boxes and, on the other hand, above all, the cooler block are relieved of load. This applies not only to the securing of the fan frame, but also to further heat exchangers, such as condensers or charge-air coolers, which form a cooling module. If all the securing points are integrated into the supporting bearings on the vehicle, the coolant cooler is completely decoupled as a carrier of the cooling module. It consequently becomes possible to reduce the size of the cooler block consisting of tubes, ribs and tube bottoms and, in particular, to dispense with stable side parts. This lowers the weight and the production costs of the coolant cooler.

In an advantageous refinement of the invention, the holding and securing means of the fan frame are arranged in the directly adjacent region of the securing tenons on the underside of the coolant boxes. Consequently, the introduction of forces from the fan frame takes place directly into the fastening tenons of the cooler or of the cooling module, the carrier of which is the cooler. Since both the fan and the electric motor for the fan are secured to the fan frame, appreciable forces arise which, according to the invention, are kept away from the sensitive cooler block.

In a further advantageous refinement of the invention, the securing and holding means are produced by injection molding in such a way that the fan frame can be placed and latched onto the coolant cooler without accessories. In this case, additionally, two upper securings on the fan frame and the coolant boxes are provided, so that the fan frame, overall, is secured to the coolant cooler at four points. As already mentioned above, the upper securing points of the fan frame may alternatively also be integrated into the upper supporting bearings of the coolant cooler, thus leading to a complete decoupling of the fan frame in the coolant cooler.

In a further advantageous refinement of the invention, the framework is stiffened in the X-direction by means of additional ribs between the coolant boxes, since side parts are not provided or are not suitable for securing the fan frame to the cooler block.

One object of the invention is also achieved by means of a fan frame having the features of claim 26. The fan frame according to the invention has at least one additional rib, along with the advantages described above.

The exemplary embodiments of the invention are illustrated in the drawing and are described in more detail below. In the drawing:

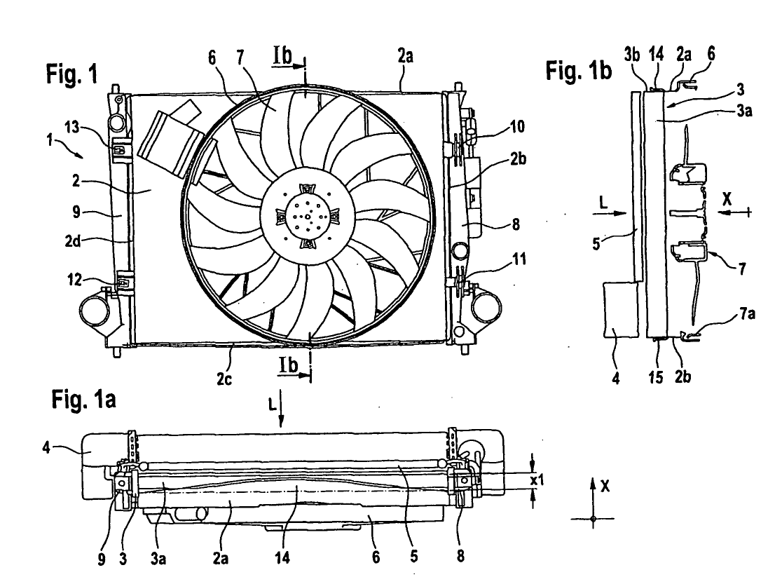

FIG. 1 shows a cooling module with a fan frame as a front view,

FIG. 1a shows the cooling module according to FIG. 1 in a view from above,

FIG. 1b shows the cooling module according to FIG. 1 in a section along the line Ib-Ib,

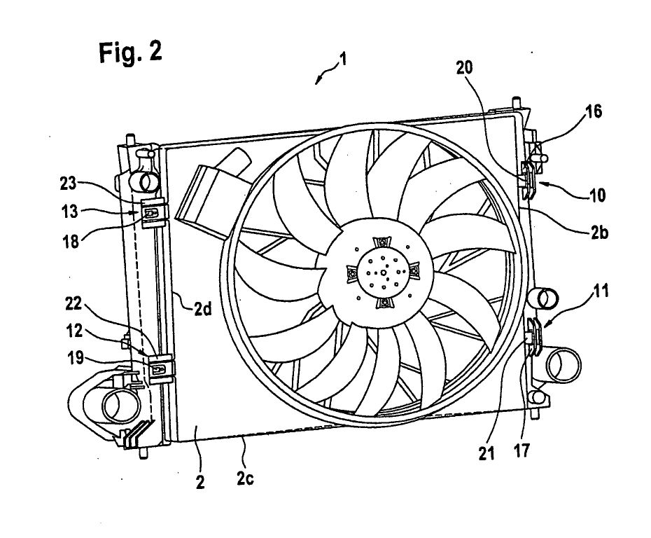

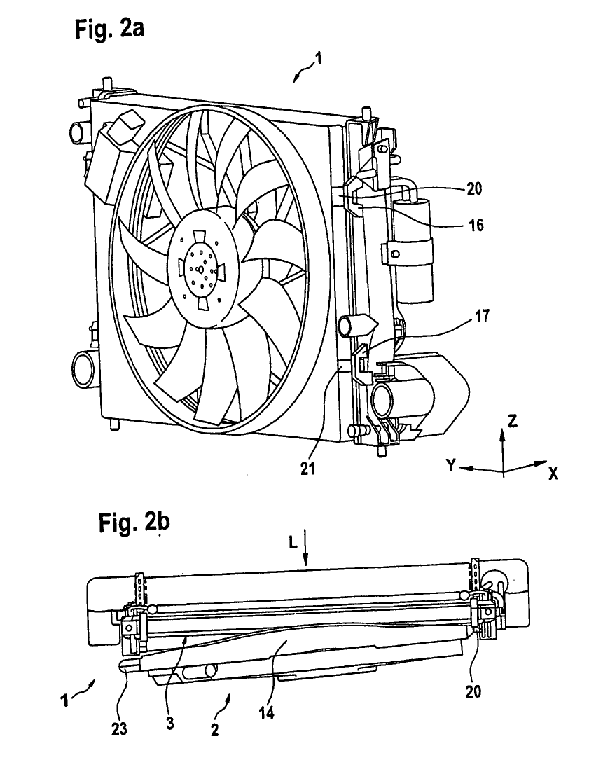

FIG. 2 shows the cooling module in a first perspective view,

FIG. 2a shows the cooling module in a second perspective view,

FIG. 2b shows the cooling module in a view from above, with the fan frame premounted,

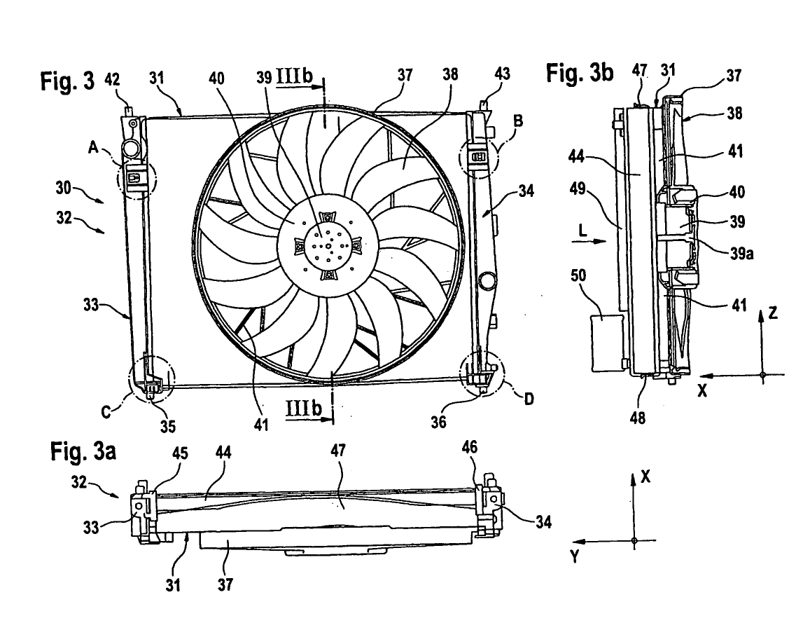

FIG. 3 shows a further exemplary embodiment of the invention with a modified fan frame securing,

FIG. 3a shows a view from above of the fan frame securing according to FIG. 3,

FIG. 3b shows a section along the line IIIb-IIIb in FIG. 3,

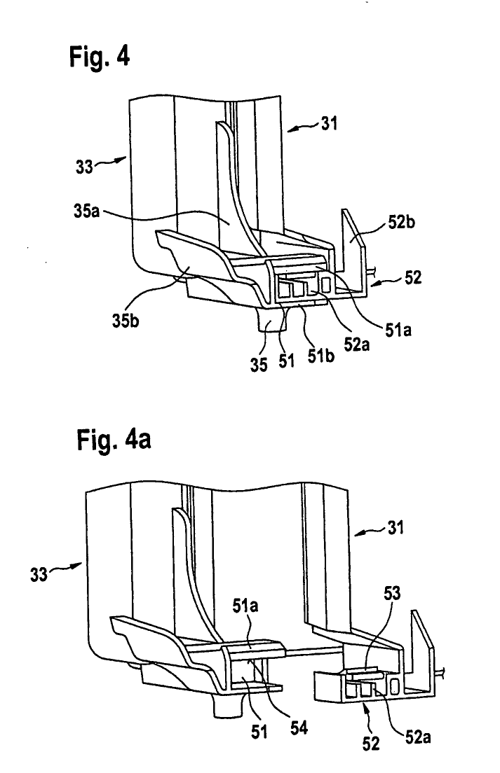

FIG. 4 shows a lower securing point of the fan frame as the detail C from FIG. 3,

FIG. 4a shows the securing point according to FIG. 4 before mounting,

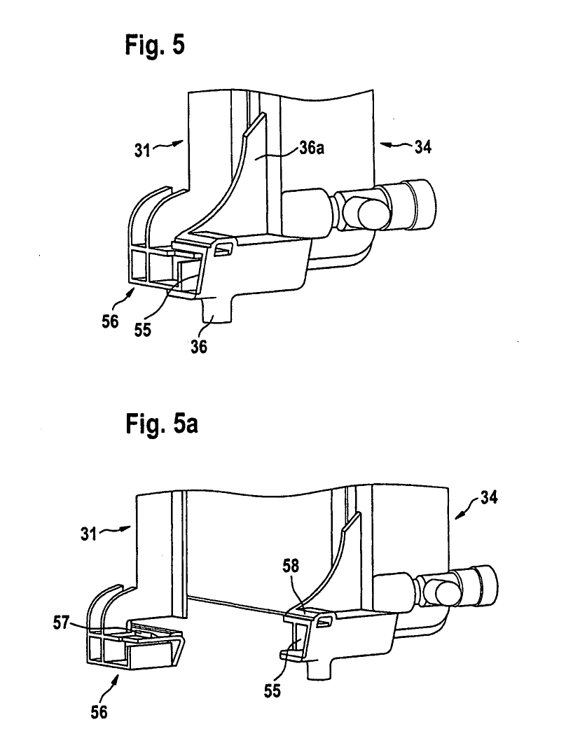

FIG. 5 shows a further securing point of the fan frame as the detail D according to FIG. 3, and

FIG. 5a shows the securing point according to FIG. 5 before mounting.

FIG. 1 shows a cooling module 1 for a motor vehicle (not illustrated) as seen in the direction of travel, that is to say in a view of a fan frame 2 arranged on the air outlet side, which is secured to the cooling module 1. As shown in FIG. 1a, the cooling module 1 consists of a coolant cooler 3, of a charge-air cooler 4 and of a refrigerant condenser 5, arranged between the two, for an air conditioning system, not illustrated, of the motor vehicle. The three heat exchangers 3, 4, 5 are connected in a way not illustrated in any more detail and not explained, to form a structural unit, to the cooling module 1 which, together with the fan frame 2, is mounted in the front engine space of the motor vehicle. Ambient air flows through the cooling module in the direction of an arrow L. The X-direction, a coordinate fixed with respect to the vehicle, is indicated by an arrow X in FIG. 1a—it corresponds to the direction of travel. The fan cowl 2 has an approximately rectangular framework, which is delimited by four sides 2a, 2b, 2c, 2d, and a frame ring 6, within which a fan 7 rotates for the conveyance of cooling air. The coolant cooler 3 has two lateral vertically arranged coolant boxes 8, 9, in each case with two securing points 10, 11 and 12, 13 which are explained in more detail in connection with the description of FIG. 2.

FIG. 1a shows the cooling module 1 in a view from above and the arrangement of the fan frame 2, in the air flow direction identified by the arrow L, behind the coolant cooler 3 which has a soldered tube/rib block 3a between the two coolant boxes 8, 9. The upper framework side 2a is followed downstream by the frame aperture 6. Arranged in front of the upper framework side 2a in the X-direction, that is to say in the direction of travel of the motor vehicle, illustrated by the arrow X, is an additional rib 14, which is produced in one piece with the framework 2 and has approximately the form of an isosceles triangle. The additional rib 14 thus has a variable depth in the X-direction, the maximum X1 being located in the middle. There, for example in the event of a deceleration of the vehicle in the X-direction, the maximum load (bending stress) occurs, which is absorbed there by the increased moment of resistance of the additional rib 14—thus, as a result of this additional rib 14, the framework of the fan frame 2 is bend-resistant in the X-direction and with respect to the bearing points 10, 11, 12, 13 on the coolant boxes 8, 9.

FIG. 1b shows a section along the line Ib-Ib in FIG. 1, that is to say through the middle of the fan frame 2 and the fan 7 which is designed as a sickle fan with a casing 7a and rotates in the frame aperture 6 with a minimal radial gap. To that extent, there is effective sealing between the circumference of the fan 7 and the frame aperture 6. The fan frame 2 bears with its two framework sides, the upper side 2a and the lower side 2b, against the coolant cooler 3, that is to say against the tube/rib block 3a; in the same way, the two vertical sides 2b, 2d, not illustrated here, bear against the coolant cooler 3, so that the fan frame 2 is sealed off with respect to the coolant cooler 3 on all sides, that is to say over the entire circumference. The upper framework side 2a is followed by the additional rib 14, a gap being left between the rib 14 and the top side 3b of the coolant cooler 3. The lower framework side 2b is followed mirror-symmetrically by an additional rib 15 which likewise extends in the X-direction over the coolant cooler 3 or the tube/rib block 3a and therefore also causes a stiffening of the fan frame 2 in the X-direction in the lower region of the framework. It can be seen clearly from this illustration that virtually no additional construction space is required for the two additional ribs 14, 15. In front of the coolant cooler in the air flow direction, the refrigerant condenser 5 is arranged in the upper region and the charge-air cooler 4 is arranged in the lower region. Overall, as seen in the X-direction, the cooling module 1 has not become deeper due to the arrangement of the stiffening ribs 14, 15, but is more bend-resistant in the X-direction. Thus, a type of construction which is flat in the X-direction is achieved for the fan frame 2, in which case it is possible to dispense with conventional side parts of the coolant cooler 3, since the fan frame 2 is self-supporting in the upper and lower unsupported region on account of the arrangement in the additional ribs 14, 15.

FIG. 2 shows a perspective, that is to say a 3-D illustration of the cooling module 1 in a view of the fan frame 2 which is secured to the coolant boxes 8, 9 at the four securing points 10, 11, 12, 13. The two securing points 10, 11 are designed on the right coolant box 8 as closed holders 16, 17, each with an insertion orifice, while the securing points 12, 13 are designed on the left coolant box 9 as snap hooks 18, 19. The fan frame 2 has on its right side 2b two insertion tabs 20, 21 and on its left side 2d two securing tabs 22, 23, each with a securing orifice.

FIG. 2a shows the cooling module 1 in another 3-D illustration, that is to say with the right coolant box 8 in the foreground. The holders 16, 17 of stirrup-shaped design can be seen clearly here, into which the insertion tabs 20, 21 of the fan frame 2 are inserted and are thus held positively in the X- and Z-direction. The system of coordinates with the three axes X, Y, Z (dimensions) is depicted on the right next to FIG. 2a.

FIG. 2b shows the cooling module 1 in a view from above, that is to say in the direction of the negative Z-axis. The fan frame 2 is illustrated here in a position in which the mounting operation has just begun, specifically by the introduction of the insertion tabs 20, 21 beveled toward the side of the cooler 3 into the stirrup-shaped holders 16, 17. In this first mounting step, the fan cowl 2 is set obliquely with respect to the plane of the cooler 3, specifically at an angle of approximately 3 degrees. This makes it easier to introduce the insertion tabs 20, 21. The fan frame 2 is subsequently folded in the direction of the coolant cooler 3, so that the securing tabs 22, 23 butt on the coolant box 9 and so that the snap hooks 18, 19 pass through them and engage behind them. The fan cowl 2 is thus fixed and secured to the coolant cooler 3. In this mounting operation, introduction and folding, the reinforcing ribs 14, 15 remain free of the tube/rib block 3a, since, during folding, the fan frame 2 is pivoted about a vertical axis (Z-axis) in the same way as in a hinge. The extremely simple mounting operation is consequently concluded without additional aids or securing means.

FIG. 3 shows, as a further exemplary embodiment of the invention, a cooling module 30 with a fan frame 31 which is secured to a coolant cooler 32 on a motor vehicle, not illustrated. The coolant cooler 32, which is the carrier of the cooling module 30, not fully illustrated here, has two plastic coolant boxes 33, 34 which are arranged vertically in the vehicle and on the underside of which securing tenons 35, 36 for supporting the vehicle are injection-molded. The fan frame 31 is secured to the coolant cooler 32 at four circled securing points A, B, C, D. The securing points A, B are designed in a similar way to the securings 12, 13 in the previous exemplary embodiment according to FIG. 2, that is to say tabs (not designated) with securing orifices are arranged on the fan frame 31, and snap hooks (not designated) are arranged on the coolant boxes 33, 34, so that the fan frame 31 can be mounted by being pressed onto the coolant cooler 32. The securing points C, D are illustrated as details in FIGS. 4 and 5 and are described in more detail there. The fan frame 31 has a frame aperture or frame ring 37 in which a fan 38, designed as what is known as a sickle fan, rotates. An electric motor 39 is connected, on the one hand, from the fan 38 via a fan hub 40 and, on the other hand, from the fan frame 31 via struts 41 partially concealed by the fan 38. The coolant cooler 32, as a carrier of the cooling module 30, is supported with respect to the vehicle, on the one hand, by the lower securing tenons 35, 36 and, on the other hand, by two further holding tenons 42, 43 which are arranged on the coolant boxes 33, 34 at the top and which are received in corresponding vehicle-side bearings, for example rubber bushes.

FIG. 3a shows the coolant cooler 32 in a view from above, with the fan frame 31 and frame ring 37. Between the coolant boxes 34, 35 is arranged a cooler block 44 which is constructed from tubes and ribs, not illustrated, preferably from flat tubes and corrugated ribs soldered to one another. The tube ends of the block 44 are received by tube bottoms 45, 46 which are themselves connected mechanically to the coolant boxes 34, 35.

An additional rib 47, which extends in the X-direction (direction of travel of the motor vehicle) over the cooler block 44, is injection-molded onto the fan frame 31 in the upper region of the latter. Said additional rib serves for stiffening the fan frame 31, just as is illustrated and described in the previous exemplary embodiment according to FIG. 1 to 2b. To that extent, an additional rib is likewise also arranged on the underside (not visible here).

FIG. 3b shows a section along the line IIIb-IIIb according to FIG. 3, that is to say a section through the cooler block 44 and an axial section through the fan 38 which is designed as a casing fan and rotates in the frame ring 37. As already mentioned, the fan 38 is driven by the fan motor 39, an electric motor, via a motor shaft 39a. The electric motor 39 is connected to the fan frame 31 and supported via the struts 41 in a way not illustrated in any more detail. The fan frame 31 thus carries the fan 38 and the fan motor 39. A further additional rib 48 is arranged on the underside of the cooler block 44 mirror-symmetrically with respect to the additional rib 47 arranged at the top, as described above with regard to the first exemplary embodiment. The air flow direction is illustrated by an arrow L and the coordinates X, Z by arrows X, Z. Arranged in front of the cooler block 44 in the X-direction are a condenser 49 and a charge-air cooler 50 which complete the cooling module (these two heat exchangers 49, 50 are not illustrated in FIG. 3a).

FIG. 4 shows the detail C from FIG. 3, that is to say a securing point of the fan frame 31 on the left coolant box 33 in the region of the lower securing tenon 35. The latter is arranged so as to be offset somewhat with respect to the coolant box 33 and is supported with respect to the coolant box 33 by means of ribs 35a, 35b. The middle rib 35a is followed by a reception orifice 51 which is laterally open and is delimited upwardly and downwardly by surfaces 51a, 51b running approximately horizontally. A foot 52, which is received slideably in the reception orifice 51, is injection-molded onto the fan frame 31 in the lower corner region (securing point C). For stiffening, the foot has a ribbing 52a and lateral boundary surfaces 52b. This securing point between the fan frame 31 and coolant box 33 is designed as a fixed bearing.

FIG. 4a shows the parts 31, 33 connected according to FIG. 4, before mounting. On the foot 52, a snap hook 53 is arranged, which secures the fan frame 31, mounted in the X-direction, in the negative X-direction. The snap hook 53 latches behind an edge 54 of the surface 51a. It can be seen from the illustration that offset forces can be introduced directly from the fan frame 31 into the securing tenon 35 by the foot 52.

FIG. 5 shows the detail D in FIG. 3, that is to say the second lower securing point between the fan frame 31 and the right coolant box 34 in the surrounding region of the securing tenon 36 which is injection-molded, slightly offset, onto the coolant box 34 and is supported via a vertical rib 36a. Above the securing tenon 36, a laterally open box-shaped profile is arranged as a reception orifice 55. The fan frame 31 has injection-molded onto it a profiled foot 56 of box-shaped design which engages into the reception orifice 35.

FIG. 5a shows the connecting elements, foot 56 and reception orifice 55, before their mounting, the foot 56 having a snap hook 57 arranged on its top side and the reception orifice 55 having a corresponding edge 58. The foot is mounted with the fan frame 31 in the X-direction (cf. FIG. 3a, 3b) and is secured in the negative X-direction by the snap hook 57. This securing point is designed as a loose bearing, that is to say tolerance compensation in the Y-direction (cf. FIG. 3a) is possible here. Here, too, it becomes clear from the illustration that forces from the fan frame 31 can be introduced directly into the securing tenon 36 via the foot 56.

The fan frame 31 is mounted with its four securing points A, B, C, D in the X-direction, that is to say is pressed onto the cooler, specifically in an approximately parallel orientation, until all four snap hooks latch at the four securing points. This mounting direction also allows arrangement of the upper and lower additional rib 47, 48.

Contrary to the exemplary embodiment illustrated, the two upper securing points A, B of the fan frame 31 may also be integrated with the upper holding tenons 42, 43, that is to say in a similar way to the lower securing points C, D. The coolant cooler 32 and fan frame 31 would consequently be decoupled completely.

The securing points of further heat exchangers, for example a condenser and/or a charge-air cooler (cf. FIG. 3b), are not illustrated here—they may be integrated, in a similar way to the fan frame, into the supporting bearings of the coolant cooler, so that the latter, as a carrier of the entire cooling module, is as far as possible decoupled and is consequently relieved of load.

1. An arrangement used for securing a fan frame to a heat exchanger, the heat exchanger having at least one header with holding means, and the fan frame having a framework with securing means and with at least one additional rib for stiffening, the holding means of the header being in operative contact with one another by the securing means of the framework.

2. The arrangement used for securing a fan frame and/or additional heat exchangers to a heat exchanger, in particular as claimed in claim 1, the heat exchanger having at least one header with holding means and supporting means for a support of the heat exchanger on an abutment, and the fan frame and/or the additional heat exchangers having at least one supporting device for supporting the fan frame and/or the additional heat exchangers on the abutment and securing means, the holding means of the heat exchanger and the securing means of the fan frame and/or of the additional heat exchangers being in operative contact with one another.

3. The arrangement as claimed in claim 1, wherein the fan frame and/or the additional heat exchangers are secured solely to the header or headers of the heat exchanger.

4. The arrangement as claimed in claim 1, wherein the header is arranged laterally on the heat exchanger, and the securing means are arranged laterally on the fan frame and/or the additional heat exchanger.

5. The arrangement as claimed in claim 1, wherein the heat exchanger has two headers which are arranged, in particular, on opposite sides of the heat exchanger.

6. The arrangement as claimed in claim 1, wherein an additional rib of the fan frame is arranged between two headers of the heat exchanger, in particular in an edge region of the fan frame.

7. The arrangement as claimed in claim 1, wherein the additional rib has a length which corresponds to the distance between two headers.

8. The arrangement as claimed in claim 1, wherein an additional rib has a depth (X) which corresponds approximately to the depth of the tube/rib block of the heat exchanger.

9. The arrangement as claimed in claim 1, wherein the depth X of an additional rib is variable along the rib and has a maximum X1 at mid-length.

10. The arrangement as claimed in claim 1, wherein the additional rib has essentially the same wall thickness as the framework of the fan frame.

11. The arrangement as claimed in claim 1, wherein one or more additional ribs, cover a tube/rib block of the heat exchanger.

12. The arrangement as claimed in claim 1, wherein the fan frame is produced as a plastic part and the additional rib can be injection-molded onto the framework.

13. The arrangement as claimed in claim 1, wherein the supporting means comprise a securing tenon.

14. The arrangement as claimed in claim 1, wherein the securing means of the fan frame and/or of the additional heat exchangers can be inserted and/or latched into the holding means of the header or the holding means of the header can be inserted and/or latched into the securing means of the fan frame and/or of the additional heat exchangers.

15. The arrangement as claimed in claim 1, wherein the holding means on one header are designed as holders with insertion orifices and on another header as snap hooks, and in that the securing means on the fan frame are designed on one side as insertion tabs and on the opposite side as securing tabs with latching orifices, and in that the fan frame can be inserted with the insertion tabs into the holders, can subsequently be folded and can be latched by means of the snap hooks and the securing tabs.

16. The arrangement as claimed in claim 1, wherein the securing means are designed as tabs of the fan frame and the holding means on the header are designed as snap hooks.

17. The arrangement as claimed in claim 1, wherein the securing means of the fan frame are designed as ribbed feet injection-molded onto the framework in the lower region, and in that the holding means on the header are designed as reception orifices, and in that the feet can be pushed into the reception orifices.

18. The arrangement as claimed in claim 1, wherein snap hooks are arranged on the feet and edges are arranged on the reception orifices, and in that the snap hooks can be latched with the edges.

19. The arrangement as claimed in claim 1, wherein the foot with the reception orifice is designed as a fixed bearing and the foot with the reception orifice is designed as a loose bearing.

20. The arrangement as claimed in claim 1, wherein the securing tenons are arranged below the reception orifices.

21. The arrangement as claimed in claim 1, wherein the supporting means of the heat exchanger and the supporting device of the fan frame and/or of the additional heat exchangers are arranged in a common securing region and, in particular, are integrated in one another.

22. The arrangement as claimed in claim 1, wherein the fastening means of the fan frame and the holding means of the header are arranged in the adjacent region of the supporting means and, in particular, form the common securing regions.

23. The arrangement as claimed in claim 1, wherein the heat exchanger is a coolant cooler, in particular for motor vehicles.

24. The arrangement as claimed in claim 1, wherein the coolant cooler is part of a cooling module for a motor vehicle.

25. The arrangement as claimed in claim 1, wherein the abutment is part of a motor vehicle framework.

26. A fan frame, in particular for an arrangement as claimed in claim 1, which has a framework with securing means and at least one additional rib.

27. The fan frame as claimed in claim 26, characterized by an approximately rectangular horizontal projection.
